(19) United States
(12) Patent Application Publication
(10) Pub. No.: US 2004/0159928 A1
(43) Pub. Date: Aug. 19, 2004

(54) Supporting structure for a chip and method for producing the same

(75) Inventors: Knut Kahlisch, Dresden (DE); Henning Mieth, Jahnsdorf (DE); Stephan Blaszczak, Freyburg (DE); Martin Reiss, Regensburg (DE)

Correspondence Address: Harold C. Moore, Maginot, Moore & Beck, Bank One Center/Tower, 111 Monument Circle, Suite 3000, Indianapolis, IN, 46204-5115, US

(73) Assignee: Infineon Technologies AG, Munich (DE)

(21) Appl. No.: 10/719,999

(22) Filed: Nov. 21, 2003

(30) Foreign Application Priority Data
Nov. 22, 2002 (DE) 10254648.7

(51) Int. Cl. H01L 23/02

(52) U.S. Cl. 257/678

(57) ABSTRACT

A supporting structure for a chip includes a supporting substrate with a bond opening therein and an interconnect layer on the supporting substrate. In the interconnect layer, a bonding channel overlapping with the bond opening is formed. The supporting structure further includes an escape prevention structure for the bonding channel to enable escaping of air from the bonding channel and to prevent the encapsulation material from escaping from the bonding channel on introducing encapsulation material into the bonding channel after the applying of a chip to the supporting structure.

### BACKGOUND OF THE INVENTION

1. Field of the Invention

The present invention relates to supporting structures for a chip and more particularly to supporting structures with a bonding channel.

2. Description of the Related Art

In many semiconductor production processes, chips or devices are provided with a package to ensure protection thereof. In the prior art, CSP methods (CSP=chip size package), such as a μBGA method (μBGA method=micro ball grid array), FBGA methods (FBGA=fine-pitch ball grid array) or BOC methods (BOC=board on chip) are employed for housing chips.

In the production of miniature packages, a specially preprocessed support substrate is typically used in the prior art. Here, both a voltage-absorbing bilaterally adhesive elastomer and a printed adhesive layer are disposed on the supporting substrate, so that a so-called bonding channel is recessed in an end-to-end manner by division. The bonding channel enables electrically connecting pads on a chip, which is attached on the supporting substrate, by means of wires that are passed through the bonding channel for example to terminal regions of the supporting substrate.

Typically, the wire bonding takes place after connecting the chip with the supporting substrate. Here, the wires are inserted into the bonding channel by means of known methods from outside via bond openings, in order to then being connected to the pads on the chip. The bonding channel typically has a width of about 0.7 to 1.2 mm, wherein the length thereof may extend across the entire supporting substrate. Thereby, by means of a single channel, an electrical connection for a plurality of pads of the chip may be provided.

After the above-mentioned wire bonding has been performed, the bonding channel is encapsulated, i.e. more specifically filled out with an encapsulation material or potting material to mechanically mount and isolate the wires against each other.

For example, the encapsulating includes the introducing of a viscous, isolating mass. In the prior art, the encapsulating is performed for example with a knife-spreading method or a dispensing method, in which a needle is introduced into the bonding channel, and the encapsulation material is then introduced into the bonding channel through the needle channel.

Furthermore, it is known in the prior art, to encapsulate the bonding channel by means of an injection-molding method, in which the encapsulation mass is injected into the bonding channel by means of overpressure. After introducing the potting mass, the channel is closed, with the wires being mechanically anchored in the encapsulation mass after curing.

The supporting substrate used in the prior art with the bilaterally open bonding channel, however, has the disadvantage that the encapsulation mass flows out more or less strongly over the ends of the bonding channel depending on the viscosity when encapsulating the bonding channel.

As it is known, the cross-section of the bonding channel ends is determined by the silicon size, i.e. the chip size, the width of the active region of the bonding channel, and the elastomer thickness or adhesive layer thickness. In order to prevent the flowing out of the potting mass from laterally open bonding channel ends, it is required in the prior art to correspondingly tune its viscosity and rheology or absolutely keep to a time-critical process sequence. Both, however, can only be realized under yield losses.

Furthermore, laterally closing of the bonding channel is disadvantageous, because, when encapsulating the bonding channel, air or another gas residing in the bonding channel remains in the bonding channel due to an incomplete displacement, whereby air inclusions, such as bubbles or holes form in the encapsulation mass.

### SUMMARY OF THE INVENTION

It is the object of the present invention to provide a supporting structure for a chip, in which an improved encapsulation of the bonding channel is achieved.

In accordance with a first aspect, the present invention provides a supporting structure for a chip, having a supporting substrate with a bond opening therein; an interconnect layer on the supporting substrate (100), in which a bonding channel overlapping with the bond opening (116) is formed; and an escape prevention structure for the bonding channel, to enable escaping of air from the bonding channel and to prevent the encapsulation material from escaping from the bonding channel on introducing encapsulation material into the bonding channel after the applying of a chip to the supporting structure.

In accordance with a second aspect, the present invention provides a method for producing a supporting structure for a chip, with the steps of preparing a supporting substrate with a bond opening; creating an interconnect layer on the supporting substrate, so that a bonding channel is formed in the interconnect layer; and creating an escape prevention structure for the bonding channel, so that the escape prevention structure is formed to enable escaping of air from the bonding channel and to prevent the encapsulation material from escaping from the bonding channel on introducing encapsulation material into the bonding channel after the applying of a chip to the interconnect layer.

The present invention is based on the finding that, when encapsulating the bonding channel, it is thereby achieved that air or another gas residing in the bonding channel can be forced to the outside, when encapsulating, via a specially provided escape prevention structure or vent structure, which at the same time prevents encapsulation material from escaping from the bonding channel.

In one embodiment, for avoiding leaving of the encapsulation mass, it is being aimed at reducing the capillary effect occurring at the escape prevention structure, such that the pulling out of the encapsulating mass through the escape prevention structure due to occurring capillary forces is prevented. For example, in one embodiment, an escape of the encapsulation mass occurring in the prior art in bonding channels with laterally open ends due to capillary forces may be achieved by narrowing the bonding channel cross-section at the ends by means of barrier structures.

An advantage of the present invention is that a realization of the escape prevention structure may take place in a flexible manner. This allows adapting and optimizing the escape prevention structure with reference to respective encapsulation methods, encapsulation materials, bonding channel dimensions or shapes. Flexibly designing the escape prevention structure may for example be achieved by changing the shape, the form, and the arrangement with reference to a bonding channel or the dimension of the escape prevention structure. Furthermore, various kinds of escape prevention structures may be provided. By the variation of the escape prevention structure, it is made possible to prevent contamination of active substrate regions in the future package.

In one embodiment, the escape prevention structure is formed at the laterally open end of the bonding channel, so that a cross-section of the bonding channel at the end is decreased relative to the cross-section of the rest of the bonding channel.

Providing a bonding channel with laterally open ends known from the prior art has the advantage that only a slight modification of the bonding channel is required, such as by providing the barrier structure, in order to enable the advantageous encapsulation of the bonding channel according to the invention. Thereby, in the production, the methods and designs known from the prior art may be used, whereby low production cost and quick conversion to a production process can be achieved.

The escape prevention structure may be a slot-like opening formed at the lateral end of the bonding channel by providing a barrier structure for blocking the cross- section of the end. The barrier structure is for example a layer disposed at the lateral end, which is deepened relative to the layer forming the bonding channel or has embossings forming individual vent flutes. This enables simple and inexpensive production of the escape prevention structure.

A slot formed by the barrier structure may be formed both in a horizontal direction and a vertical direction with reference to the supporting substrate. Furthermore, the escape prevention structure may include an exit opening whose cross-section tapers in the exit direction.

The barrier structure for narrowing the cross-section may be connected to the interconnect layer forming the bonding channel. Furthermore, in one embodiment, the barrier structure for forming vent openings at a lateral open end of the bonding channel may be disposed in a spaced manner to the interconnect layer. The barrier structure may extend across the entire height of the interconnect layer, whereby the barrier structure may be in contact with the chip when applying a chip to the interconnect layer.

Furthermore, the barrier structure may have a smaller height than the interconnect layer, so that the barrier structure is spaced from a chip applied to the interconnect layer. The barrier structure may have arbitrary shapes, such as cylindrical shape or a bump shape, wherein, by a convex design of the lateral and/or top surface of the barrier structure, an advantageous shape is achieved that enables displacement of the air without the formation of disadvantageous flows, and also provides an increased wetting area for the encapsulation mass, so that pulling out of the encapsulation mass due to capillary forces is prevented by the wetting of the barrier structure.

The escape prevention structure may also include a plurality of openings, which are arranged in a perforation structure, for example.

In a further embodiment, the escape prevention structure is disposed in a supporting substrate, whereby the bonding channel may be formed with completely closed sidewalls. The escape prevention structures may include recesses in the supporting substrate, such as slots, which connect the bonding channel to the outside environment.

In one embodiment, the recesses are formed on a surface of the supporting substrate on which the interconnect layer is disposed. The recesses extend in a direction of the surface, such that the lateral wall or boundary of the bonding channel is traversed, so that a connection from the bonding channel to the outside is formed.

In a further embodiment, in which a recess for venting is formed in the region of the bonding channel on the supporting substrate, the recess extends in a direction perpendicular to the supporting substrate from the surface of the supporting substrate on which the interconnect layer is formed to the opposing surface.

The encapsulation of the bonding channel may be performed by means of methods known in the prior art, such as by means of a pressure-assisted method, a closed knife- spreading system or a dispensing process. Using suitable encapsulation materials, such as epoxy resin, the use of pressure-assisted methods, such as injection-molding-like processes enables high quality of the encapsulation.

The escape prevention structure may be applied as a pre- shaped structure on the supporting structure in a production process. For example, the escape prevention structure may be formed from an elastomer material having a bilaterally adhesive surface. Preferably, in this embodiment, creating the escape prevention structure takes place concurrently with creating the interconnect layer forming the bonding channel.

In a further embodiment, the escape prevention structure is realized by an adhesive layer that may for example be deposited by means of a printing method.

Furthermore, in a production process, the escape prevention structure may also take place by embossing a deposited escape prevention structure layer. The embossing may for example take place after depositing the escape prevention structure layer by compression molding or pressure molding thereof.

In an embodiment in which the escape prevention structure is provided on the supporting substrate, it is created for example by ablating material of the supporting substrate, such as by etching or cutting.

### BRIEF DESCRIPTION OF THE DRAWINGS

These and other objects and features of the present invention will become clear from the following description taken in conjunction with the accompanying drawing, in which:

FIGS. 1a-b are schematic views of a cross-section and a plan view onto a supporting structure according to an embodiment in which a cross-section of a bonding channel tapers in the exit direction;

FIGS. 2a-b are schematic views of a cross-section and a plan view onto a supporting structure according to an embodiment in which a horizontal flute is provided for preventing;

FIGS. 3a-b are schematic views of a cross-section and a plan view onto a supporting structure according to a further embodiment in which a horizontal flute is provided for venting.

FIGS. 4a-b are schematic views in which a cross-section and a plan view of a supporting structure are illustrated according to a further embodiment of the present invention in which a barrier structure is disposed in a bonding channel; and

FIGS. 5a-b are schematic views in which a cross-section and a plan view of a supporting structure are illustrated according to a further embodiment of the present invention in which an escape prevention structure is formed in the supporting substrate.

### DESCRIPTION OF THE PREFERRED EMBODIMENTS

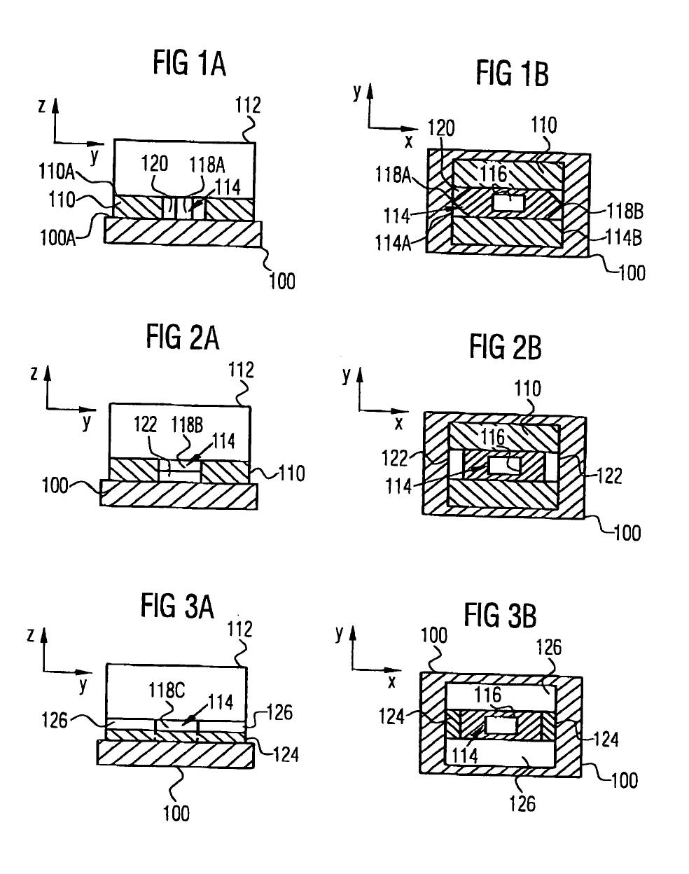

In the following, with reference to FIGS. 1a to 5b, different embodiments of a supporting structure for a chip are explained in more detail. Elements of the supporting structure that are similar in the various embodiments are designated with like reference numerals each in the figures. FIG. 1a shows a schematically illustrated cross-section through a supporting structure with an applied chip according to an embodiment of the present invention. An interconnect layer 110 with a bonding channel 114 formed therein is disposed on a surface 100a of the supporting substrate 100. By a bonding channel, a recess is to be understood that enables to pass wires from a pad of a chip 112 applied on an outer surface 100a of the interconnect layer 110 to the surface 100a of the supporting substrate 100 opposing the chip 112. According to FIG. 1b showing a plan view onto the supporting structure without the chip 112, the bonding channel 114 is formed by a division of the interconnect layer 100. In other words, the bonding channel 114 is formed by a horizontally extending elongated recess in the interconnect layer 110, with it being open at lateral ends 114a and 114b.

The supporting substrate 100 may be a semiconductor material, a ceramic material, or other materials known in the prior art, wherein the supporting substrate 100 may include one or more layers.

The supporting substrate 100 includes a bond opening 116 that is formed in the supporting substrate in an overlapping manner with the bonding channel 114. The bonding channel 114 enables passing through wires for connecting them to pads of the chip 112, and encapsulating the bonding channel, wherein encapsulation material is introduced into the bonding channel 114 via the bond opening 116.

The supporting structure further comprises, at the lateral ends 114a and 114b of the bonding channel 114, vertical vent slots or slits 118a that are formed by triangular barrier structures 120 in the bonding channel 114. The vent slots 114a extend in a direction perpendicular to the supporting substrate 100 (z-axis) across the entire thickness of the interconnect layer 110, and are each connected to the interconnect layer 110 at the lateral ends 114a and 114b.

The triangular barrier structures 120 narrow the channel at the ends of the bonding channel 114, so that the channel cross-section increasingly tapers in the exit direction. This enables an optimum quality to be achievable in encapsulating the bonding channel 114 by avoiding the formation of cavities and inclusions. The tapering cross-section of the channel at the lateral ends 114a and 114b enables forcing out the air, without a projecting structure or an edge extending in the way of the air flow, whereby the formation of disadvantageous flows, such as air eddies, is effectively prevented. The minimum opening cross-section occurring at the ends of the sides is preferably suitably chosen depending on parameters influencing the capillary effect, such as the viscosity of the encapsulation material, the channel width and height, to disable leaving of the encapsulation mass due to the capillary effect.

For creating the vent slots 118a, the barrier structures 120 are preferably preformed at the required parts of the interconnect layer 110. With this, the barrier structures 120 and the interconnect layer 110 preferably comprise a bilaterally adhesive layer, which may for example include elastomer material. This enables to stick the interconnect layer 110 and the barrier structures 120 on the supporting substrate, wherein the chip 112 may be applied on the outer surface 110a of the interconnect layer 110 by the bilaterally adhesive material. With this, the barrier structures 120 and the interconnect layer 110 may already be formed in the desired shape prior to applying to a supporting substrate, whereby production is simplified.

In one embodiment, the interconnect layer 110 and the barrier structures 120 are created by means of depositing an adhesive layer onto the supporting substrate 100, such as by printing. Furthermore, known structuring techniques, which may for example include the usage of a mask, may also be used for forming the interconnect layer and/or the barrier structures.

FIGS. 2a and 2b show a further embodiment of the present invention, in which, by contrast to the embodiment explained with reference to FIGS. 1a and 1b, the escape prevention structure is formed by a horizontal vent flute 118b, so that a vent slot or a vent slit for venting is formed by the vent flute when applying the chip 112. The horizontal vent flute 118b is formed by means of a barrier structure 122 that is deepened in a direction perpendicular to the supporting substrate 100 (z direction) opposite the interconnect layer 114 across the entire width of the channel, so that the vent flute 118b extends in a horizontal direction across the entire width of the channel. Furthermore, groove-shaped recesses or depressions may also be provided in the barrier structure, for example to emboss individual longitudinal flutes that may also be formed in a regular arrangement.

Preferably, the barrier structure 122 as well as the interconnect layer 114 has a bilaterally adhesive elastomer. The elastomer consists of a part that is laminated onto the substrate. In this embodiment, the barrier structure 122 is preferably created after depositing the interconnect layer by subsequent deepening the layer at the lateral ends, such as by compression or pressure molding. Thereby, the vent flute is embossed into the extension of the bonding channel.

Alternatively to the above-described creating the vent flute by deepening, a vent flute may also be formed by creating raised structures or spacers on a frame, which is subsequently explained with reference to FIGS. 3a and 3b.

For this, the first layer 124 is created in a frame shape on the supporting substrate 100, wherein, by the layer 124, a frame structure with lateral walls is formed, which enclose an inside space determining the region of the future bonding channel 114. The depositing of the layer 124 may for example take place by means of printing an adhesive layer. In a subsequent step, a further layer 126 is deposited onto the layer 124 as a spacer onto the lateral walls of the frame structure. The depositing of layer 126 onto the preprinted frame-shaped layer 124 may take place by means of a second printing process.

The layer 126 is deposited, such that it does not extend completely across the sidewalls. Thereby, a vent flute 118c is formed in the respective recessed regions, i.e. the regions in which the layer 126 is not formed. In the embodiment according to FIGS. 3a and 3b, the bonding channel 114 has an elongated shape according to the embodiments explained with reference to FIGS. 1a, b and 2a, b. In the embodiment shown, the layer 126 is deposited in two parts, such that the bonding channel 114 develops, with the vent flute 18c being formed each at the lateral ends 114a and 114b thereof and extending across the entire width of the bonding channel 114.

The creation of the vent flutes according to the production methods described with reference to FIGS. 2a and 2b as well as 3a and 3b enables the simple creating of the escape prevention structures according to the invention, whereby the production costs are kept low. Furthermore, by the use of a simple geometric design, i.e. a flute extending across the entire width of the bonding channel, an inexpensive creating of the bonding channel is favored.

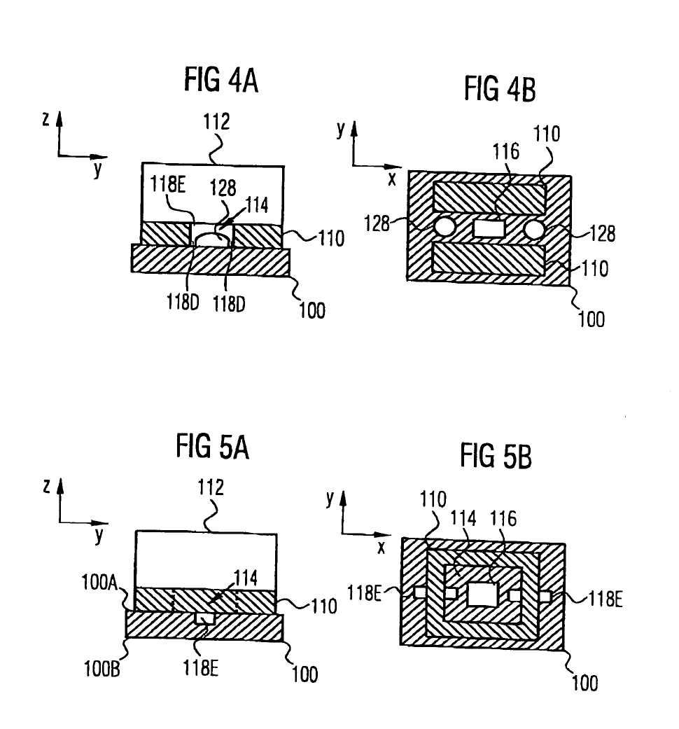

FIGS. 4a and 4b show a further embodiment of the present invention, in which, for forming the escape prevention structure, a barrier structure 128 is provided, which is disposed at the lateral ends 114a and 114b of the bonding channel. The bonding channel 114 is formed in two parts by the depositing of the interconnect layer 110, so that the lateral ends 114a and 114b are open. In this embodiment, the barrier structure 128 disposed on the supporting substrate 100 has a bump-like shape with convex surfaces. As can be seen in FIG. 4a, the barrier structure 128 includes a convexly formed top surface. Furthermore, according to FIG. 4b, the barrier structure 128 has a circular shape in a plan view onto the supporting substrate 100.

The barrier structure 128 is disposed in a spaced manner to the interconnect layer 110 at each the lateral ends 114a and 114b, so that lateral exit slots 118d each result between the barrier structure 128 and the interconnect layer. Furthermore, the barrier structure 128 has a smaller height perpendicular to the supporting substrate (z axis) than the interconnect layer 110, so that a distance between the barrier structure 128 and the chip 112 is created in disposing the chip 112 on the interconnect layer 110, whereby a further exit opening 118 is formed. Accordingly, in this embodiment, when encapsulating the bonding channel, the air flows out both at the lateral slots 118d between the barrier structure 128 and the interconnect layer 110 and via the opening 118e formed between the barrier structure 128 and the chip 112. Although the barrier structure 128 is disposed in the bonding channel 114 in the embodiment, in other embodiments, the barrier structure may be disposed at the lateral ends 114a and 114 partially or also completely outside the bonding channel.

By the convex design of the barrier structure 128, an aerodynamically advantageous shape with low flow resistance (C_{w} value) is achieved, which enables advantageous forcing out of the air with low stagnation pressure. Furthermore, by the barrier structure with convex shape, additional wetting area is provided that causes retaining the encapsulation mass in the bonding channel due to the capillary forces acting between the barrier structure and the encapsulation mass.

A further embodiment of the present invention is illustrated in FIGS. 5a and 5b. In contrast to the embodiments explained above, an escape prevention structure 118f is formed in the supporting substrate 100 in this embodiment. The escape prevention structure 118f extends as a slot-shaped recess transversally across the lateral walls of the bonding channel 114. This enables the venting of the bonding channel even if it is laterally completely closed, as provided in the embodiments described.

In a further embodiment, an escape prevention structure may also include a recess in a supporting substrate, which extends in the vertical direction (z axis) through the entire supporting substrate 100, i.e. from the surface 100a to an opposing outer surface 100b. With this, the escape prevention structure is disposed in the region of the channel 114, preferably in a suitably chosen distance to the bond opening 116, so that an advantageous air circulation results at the escaping of the air via the escape prevention structure. Corresponding to the previous embodiments, by a suitable cross-sectional area of the recess, leaving of the encapsulation mass through the recess is prevented.

Although a certain embodiment of the vent structure is shown each in the various embodiments, the respective embodiments may also be combined with each other. For example, in one embodiment, both an escape prevention structure in the supporting substrate and a barrier structure disposed at a lateral end of the bonding channel are provided.

While this invention has been described in terms of several preferred embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

What is claimed is

1. A supporting structure for a chip, comprising:
a supporting substrate with a bond opening therein;
an interconnect layer on the supporting substrate, in which a bonding channel overlapping with the bond opening is formed; and
an escape prevention structure for the bonding channel, to enable escaping of air from the bonding channel and to prevent the encapsulation material from escaping from the bonding channel on introducing encapsulation material into the bonding channel after the applying of a chip to the supporting structure.

2. The supporting structure of claim 1, wherein the escape prevention structure is designed to prevent escaping of the encapsulation material due to the capillary effect.

3. The supporting structure of claim 1, wherein the escape prevention structure includes an opening with such a cross-sectional area, so that escaping of the encapsulation material caused by the capillary effect is prevented.

4. The supporting structure of claim 1, wherein the bonding channel is open at a lateral end, wherein the escape prevention structure is formed at the lateral end by a barrier structure for reducing a cross-section of the bonding channel at the lateral end.

5. The supporting structure of claim 4, wherein the barrier structure is connected to the interconnect layer.

6. The supporting structure of claim 4, wherein the barrier structure is formed integrally with the interconnect layer.

7. The supporting structure of claim 4, wherein the barrier structure extends across the entire width of the bonding channel.

8. The supporting structure of claim 4, wherein the barrier structure is formed, so that a cross-section of the bonding channel tapers in a direction to the lateral end.

9. The supporting structure of claim 4, wherein the barrier structure has a convex shape.

10. The supporting structure of claim 4, wherein the barrier structure is disposed in the bonding channel and spaced from the interconnect layer.

11. The supporting structure of claim 1, wherein the escape prevention structure includes a recess in the supporting substrate.

12. The supporting structure of claim 11, wherein the bonding channel is laterally completely closed.

13. The supporting structure of claim 11, wherein the interconnect layer is disposed on a surface of the supporting substrate, wherein the recess on the surface extends across a sidewall of the bonding channel.

14. The supporting structure of claim 11, wherein the recess is disposed in a region of the bonding channel, wherein the recess extends from a first surface of the supporting substrate to a second surface of the supporting substrate.

15. The supporting structure of claim 1, wherein a chip is disposed on the interconnect layer.

16. A method for producing a supporting structure for a chip, comprising:
preparing a supporting substrate with a bond opening;
creating an interconnect layer on the supporting substrate, so that a bonding channel is formed in the interconnect layer; and
creating an escape prevention structure for the bonding channel, so that the escape prevention structure is formed to enable escaping of air from the bonding channel and to prevent the encapsulation material from escaping from the bonding channel on introducing encapsulation material into the bonding channel after the applying of a chip to the interconnect layer.

17. The method of claim 16, wherein the step of creating an interconnect layer includes creating a frame on the supporting substrate, and the step of creating an escape prevention structure includes deepening the frame for forming a vent flute in the frame

18. The method of claim 16, wherein the step of creating an interconnect layer comprises creating a frame on the supporting substrate, and the step of creating an escape prevention structure comprises the step of applying a spacer to the frame.

19. The method of claim 16, wherein the step of creating an interconnect layer includes structuring the interconnect layer and subsequently depositing the structured interconnect layer onto the supporting substrate.

20. The method of claim 16, wherein the step of creating an interconnect layer includes printing the interconnect layer onto the supporting substrate.

21. The method of claim 16, wherein the step of creating the interconnect layer includes creating an interconnect layer with a bonding channel with a lateral open end, and the step of creating the escape prevention structure includes creating a barrier structure at the lateral open end.

22. The method of claim 21, wherein the step of creating the interconnect layer and the step of creating a barrier structure take place concurrently.
